(19) United States
(12) Patent Application Publication
(10) Pub. No.: US 2026/0122917 A1
(43) Pub. Date: Apr. 30, 2026

(54) MEMORY DEVICE AND DRIVING METHOD THEREOF

(71) Applicant: Samsung Electronics Co., Ltd., Suwon-si (KR)

(72) Inventors: Garam PARK, Suwon-si (KR); Minhyun LEE, Suwon-si (KR); Yumin KIM, Suwon-si (KR); Hyunjae SONG, Suwon-si (KR); Jeeeun YANG, Suwon-si (KR); Seung Dam HYUN, Suwon-si (KR)

(73) Assignee: Samsung Electronics Co., Ltd., Suwon-si (KR)

(21) Appl. No.: 19/097,942

(22) Filed: Apr. 2, 2025

(30) Foreign Application Priority Data
Oct. 24, 2024 (KR) 10-2024-0146957

(51) Int. Cl. H10B 63/00; G11C 13/00

(52) U.S. Cl. CPC H10B 63/845; G11C 13/0007; G11C 13/004; G11C 13/0069; H10B 63/34; G11C 2213/71; G11C 2213/79

(57) ABSTRACT

A memory device may include a substrate, a channel layer on a surface of the substrate and including a semiconductor oxide, a gate electrode on the channel layer, an electro-chemical layer between the channel layer and the gate electrode, and a gate oxide layer between the gate electrode and the electro-chemical layer, wherein the electro-chemical layer has a concentration of oxygen vacancies exceeding 10% and is capable of transferring oxygen vacancies to the channel layer or receiving oxygen vacancies from the channel layer, depending on a voltage applied to the gate electrode

### CROSS-REFERENCE TO RELATED APPLICATION

This application claims priority to Korean Patent Application No. 10-2024-0146957 filed on Oct. 24, 2024 and all the benefits accruing therefrom under 35 U.S.C. § 119, the contents of which are incorporated by reference in their entirety.

### BACKGROUND

The present disclosure relates to memory devices and driving methods thereof.

Manufacturing technology for NAND flash memory devices is developing toward improving the integration density, operating speed, and/or yield of memory devices. In order to increase the integration of memory devices, vertical NAND (VNAND) flash memory devices have been suggested.

NAND flash memory devices, including vertical NAND flash memory devices, implement memory functions through the charge trap flash (CTF) method, which applies a voltage to a gate electrode to move electrons present in a channel layer to a trap layer through the tunneling effect. However, the CTF method may need a relatively high voltage to be applied to the gate electrode, which may cause interference problems between unit cells, and thus may have limitations in reducing the thickness of the gate electrode and/or the trap layer.

Meanwhile, an electrochemical random-access memory (ECRAM) device is known that implements a memory function by applying a voltage to the gate electrode and moving ions present in the channel layer to change the electrical conductivity and/or the threshold voltage of the channel layer.

### SUMMARY

Some example embodiments of the present disclosure provide memory devices capable of implementing a memory function even when a relatively small voltage is applied to the gate electrode and/or improving integration density, by borrowing the operating principle of an electrochemical random-access memory device to improve the charge trap flash (CTF) method that causes technical problems due to interference problems between unit cells, and a driving method of the memory device.

In addition, some example embodiments of the present disclosure also provide memory devices with an improved memory window (M.W.) by increasing the movement of oxygen vacancies in the operating principle of an electro-chemical random-access memory device, and driving methods of the memory device.

The effects of example embodiments of present disclosure are not limited to those mentioned above, and other effects not mentioned will be clearly understood by those skilled in the art from the following description.

According to an example embodiment of the present disclosure, a memory device may include a substrate, a channel layer on a surface of the substrate, the channel layer including a semiconductor oxide, a gate electrode on the channel layer, an electro-chemical layer between the channel layer and the gate electrode, and a gate oxide layer between the gate electrode and the electro-chemical layer, wherein the electro-chemical layer has a concentration of oxygen vacancies exceeding 10% and is capable of transferring oxygen vacancies to the channel layer or receiving oxygen vacancies from the channel layer, depending on a voltage applied to the gate electrode.

According to an example embodiment of the present disclosure, there is provided a method of driving a memory device, which includes a substrate, a channel layer on a surface of the substrate and including a semiconductor oxide, a gate electrode between the substrate and the channel layer, an electro-chemical layer between the channel layer and the gate electrode and including oxygen vacancies, the electro-chemical layer with a concentration of the oxygen vacancies exceeding 10%, and a gate oxide layer between the gate electrode and the electro-chemical layer. The method may include transferring the oxygen vacancies present in the electro-chemical layer to the channel layer or transferring oxygen vacancies present in the channel layer to the electro-chemical layer when a voltage is applied to the gate electrode such that an electrical conductivity and a threshold voltage (Vₜₕ) of the channel layer change values different from the electrical conductivity and the threshold voltage (Vₜₕ) of the channel layer prior to the application of the voltage to the gate electrode, and performing a write operation or an erase operation as the electrical conductivity and the threshold voltage of the channel layer change.

According to an example embodiment of the present disclosure, a memory device may include a substrate, a surface of the substrate extending in a first direction, a channel layer extending along a second direction intersecting the first direction, the channel layer including a semiconductor oxide, a gate electrode surrounding at least a portion of the channel layer, an insulating layer overlapping the gate electrode at least in a portion of a region when viewed in the second direction, the insulating layer surrounding at least a portion of the channel layer, an electro-chemical layer between the channel layer and the gate electrode, a gate oxide layer between the gate electrode and the electro-chemical layer, and a source electrode electrically connected to the channel layer and a drain electrode spaced apart from the source electrode based on the first direction, wherein the electro-chemical layer is capable of transferring oxygen vacancies present therein to the channel layer or receiving oxygen vacancies from the channel layer, depending on a voltage applied to the gate electrode, a concentration of the oxygen vacancies included in the electro-chemical layer exceeds 10%, the electro-chemical layer includes a reservoir layer and an electrolyte, the reservoir layer being adjacent to the gate electrode and including oxygen vacancies, the electrolyte layer being adjacent to the channel layer, the reservoir layer is capable of transferring the oxygen vacancies present therein to the channel layer when a positive voltage is applied to the gate electrode and the channel layer is capable of transferring the oxygen vacancies present therein to the reservoir layer when a negative voltage is applied to the gate electrode, the electrolyte layer is capable of allowing the oxygen vacancies to move between the channel layer and the reservoir layer, depending on the voltage applied to the gate electrode, the reservoir layer and the electrolyte layer each independently include metal oxide having a metal element (M)-oxygen (O) bond, the metal element (M) includes at least one selected from the group consisting of transition metal elements (TM) of groups 3 to 6, and at least one of the following conditions a) to d) is satisfied: a) the metal element (M) is a group 3 transition metal element, and a ratio (O_{b3}/TM₃) of a number (O_{b3}) of oxygen atoms bonded to the group 3 transition metal elements and a number (TM₃) of group 3 transition metals is less than 1.35, b) the metal element (M) is a group 4 transition metal element, and a ratio (O_{b4}/TM₄) of a number (O_{b4}) of oxygen atoms bonded to the group 4 transition metal elements (TM₄) and a number (TM₄) of group 4 transition metals is less than 1.8, c) the metal element (M) is a group 5 transition metal element, and a ratio (O_{b5}/TM₅) of a number (O_{b5}) of oxygen atoms bonded to the group 5 transition metal elements and a number (TM) of group 5 transition metals is less than 2.25, and d) the metal element (M) is a group 6 transition metal element, and a ratio (O_{b6}/TM₆) of a number (O_{b6}) of oxygen atoms bonded to the group 6 transition metal elements and a number (TM₆) of group 6 transition metals is less than 2.7.

Details of other example embodiments are included in the Detailed Description and drawings.

### BRIEF DESCRIPTION OF THE DRAWINGS

The drawings shown in the present disclosure are according to some example embodiments, and ratios of the width, height or thickness of each component is for describing the example embodiments of the present disclosure in detail, and the ratio may be different from the actual ones. In addition, each component illustrated in the drawings may be exaggerated to describe the present disclosure in detail. In addition, in a coordinate system shown in the drawing, each axis may can be perpendicular to the others, a direction pointed by an arrow may be a +direction, and a direction opposite to the direction pointed by the arrow (a direction rotated by 180 degrees) may be a − direction, in which:

FIG. 1 schematically illustrates at least a portion of a memory device according to an example embodiment of the present disclosure;

FIG. 2 illustrates a cross-section taken along line AA′ of FIG. 1;

FIG. 3 illustrates a cross-section taken along line BB′ of FIG. 1;

FIG. 4 is an enlarged view of part P in FIG. 1;

FIG. 5 schematically illustrates at least a portion of a memory device according to an example embodiment of the present disclosure;

FIG. 6 illustrates a cross-section taken along CC′ of FIG. 5;

FIG. 7 is an enlarged view of part Q in FIG. 5;

FIG. 8 schematically illustrates at least a portion of the memory device according to an example embodiment of the present disclosure;

FIG. 9 illustrates a cross-section taken along DD′ in FIG. 8;

FIG. 10 is an enlarged view of part R in FIG. 8;

FIG. 11 schematically illustrates at least a portion of a memory device according to an example embodiment of the present disclosure;

FIGS. 12 to 16 are views for describing a method of manufacturing a memory device according to an example embodiment of the present disclosure;

FIGS. 17 to 20 schematically illustrate at least a portion of a memory device to describe a method of driving the memory device according to an example embodiment of the present disclosure;

FIG. 21 is a set of graphs showing characteristics of a drain-source current (I_{DS}) with respect to a gate-source voltage (Vas) of a memory device according to examples and a comparative example of the present disclosure;

FIG. 22 is a graph showing results of analyzing electro-chemical layers of memory devices according to examples and comparative examples of the present disclosure, using secondary ion mass spectrometry (SIMS); and

FIG. 23 is a graph showing results of measuring the number of oxygen (O) bonded with a metal element (Hf) and the ratio of the oxygen to the metal element (Hf) (O/Hf) for a metal oxide included in electro-chemical layers of memory devices according to examples and comparative examples of the present disclosure, using X-ray photoelectron spectroscopy (XPS).

### DETAILED DESCRIPTION

Prior to the detailed description of the present disclosure, it should be noted that terms or words used in the present specification and claims may not be construed as being limited to their usual or dictionary meanings. In addition, terms or words should be interpreted to have a meaning or concept that is consistent with the technical idea of the present disclosure based on the principle that the inventors are capable of appropriately defining the concept of the term to best describe their disclosure. The example embodiments described in the present specification and configurations illustrated in the drawings are merely some example embodiments of the present disclosure and may not represent all of the technical ideas of the present disclosure. Accordingly, there may be various equivalents and variations capable of replacing the example embodiments or configurations at the time of filing of the present disclosure.

Like reference numerals or marks presented in each of drawings attached to the present specification may represent components or elements that perform substantially the same functions. For convenience of description and understanding, the same reference numbers or symbols may be used in different example embodiments. That is, even though components having the same reference number are depicted in a plurality of drawings, the plurality of drawings may not all represent one example embodiment.

When a component is described as being “on” or “in contact with” another component in the present specification, it is to be understood that the component may be directly on or connected to the other component, but that there may be another component present between the components.

When a component is described as being “above” another component in the present specification, it is meant that the component is present above the another component in a vertical direction, and it is to be understood that the components may be in direct contact or connected or still another component is present between the components. Further, when a component is described as being “below” another component in the present specification, it is meant that the component is present below the another component in the vertical direction, and it is to be understood that the components may be in direct contact or connected or still another component is present between the components.

When a component is described as being “directly on,” “adjacent to,” or “in contact with” another component in the present specification, it is to be understood that no other component is present between the components. Other similar expressions that describe positional relationships between components may be interpreted in the same way.

When a component is described in the present specification as being “disposed” on (on the surface of) another component, it is to be understood that the component is in contact with or spaced apart from the surface of the other component, but is present in a corresponding position.

In the following description, any references to singular may include plural unless expressly stated otherwise in the context. It is to be understood that the terms “includes” and/or “comprises”, when used in the present specification, specify the presence of stated features, numbers, steps, operations, elements, components, or combinations thereof, but do not preclude the presence or addition of one or more other features, numbers, steps, operations, elements, components, or combinations thereof.

In the description below, expressions such as an upper side, an upper surface, a lower side, a lower surface, a side surface, a front surface, a rear surface, or the like, are expressed based on a direction shown in the drawing, and may be differently expressed when the direction of a corresponding object changes.

Terms including ordinal numbers, such as “first,” “second,” etc., may be used in the present specification and claims to distinguish between components. The ordinals are sometimes used to distinguish between identical or similar components, and the use of the ordinals should not be interpreted in a limited way in the meaning of the terms. For example, components associated with the ordinals should not be construed as limiting the order of use or arrangement, etc., by their numbers. The ordinals may be interchangeably used as needed.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Unless specifically limited in the present specification, units of physical properties may be applied in the SI unit system.

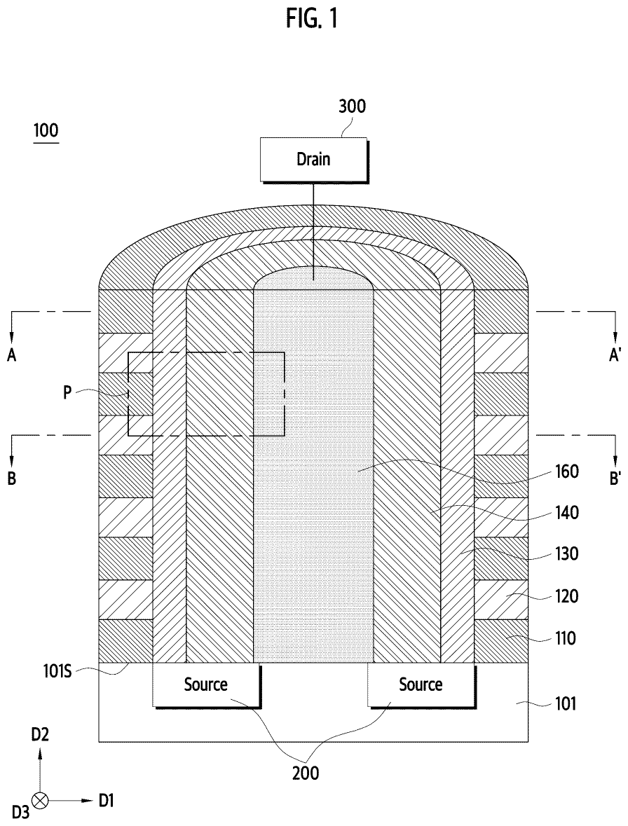

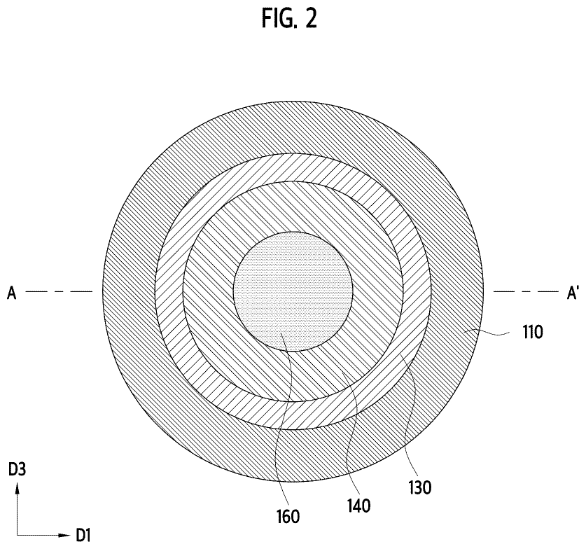

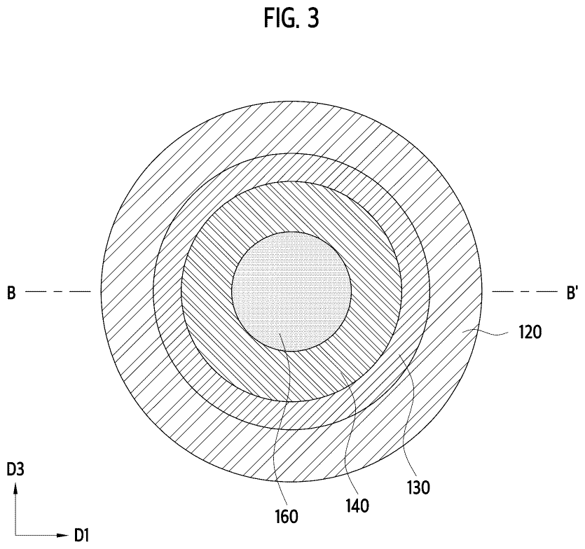

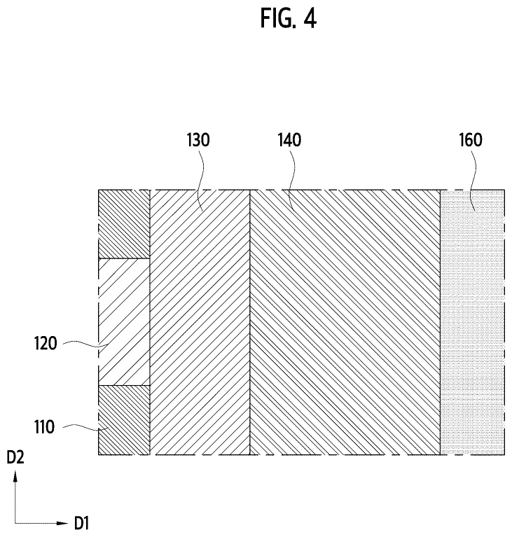

FIG. 1 schematically illustrates at least a portion of a memory device 100 according to an example embodiment of the present disclosure. FIG. 2 illustrates a cross-section taken along line AA′ of FIG. 1. FIG. 3 illustrates a cross-section taken along line BB′ of FIG. 1. FIG. 4 is an enlarged view of part P in FIG. 1.

The memory device 100 according to an example embodiment of the present disclosure may be, for example, a non-volatile memory device. In one example, the non-volatile memory device may be a flash memory, a read only memory (ROM), a hard disk, a diskette drive, a magnetic tape, or an optical disc, but is not limited thereto. In one example, the non-volatile memory device may be a flash memory. In one example, the flash memory may be a NAND flash memory, and specifically may be a planar NAND flash memory or a vertical NAND flash memory. In one example, the memory device 100 may be a planar NAND flash memory device or a vertical NAND flash memory device.

The memory device 100 according to an example embodiment of the present disclosure may include a substrate 101, a gate electrode 120, a gate oxide layer 130, an electro-chemical layer 140, and a channel layer 160.

The substrate 101 according to an example embodiment of the present disclosure is not particularly limited, but may be a silicon semiconductor substrate, a plastic substrate, a glass substrate, a compound semiconductor substrate, a ceramic substrate, or a silicon-on-insulator (SOI) substrate. In one example, the substrate 101 may include, although not separately illustrated, an impurity region due to doping, a peripheral circuit for selecting and controlling an electronic element such as a transistor or a memory cell, or the like. In one example, the gate electrode 120, the gate oxide layer 130, the electro-chemical layer 140, and the channel layer 160 may be disposed on a surface 101S of the substrate.

In the present specification, a first direction D1 may be a direction parallel to the surface 101S of the substrate, as illustrated in FIG. 1. A second direction D2 may refer to a direction intersecting the first direction D1, and specifically, the second direction D2 may be a direction perpendicular to the surface 101S of the substrate while intersecting the first direction D1. A third direction D3 may be a direction intersecting the first direction D1 as illustrated in FIG. 1, but is parallel to the surface 101S of the substrate.

The gate electrode 120 according to an example embodiment of the present disclosure may be electrically connected to a word line. In one example, the gate electrode 120 may include a conductive material. In the present specification, the conductive material may include one or more selected from the group consisting of metal, metal nitride, metal silicide, and metal oxide. In the present specification, the metal may include one or more selected from the group consisting of gold (Au), silver (Ag), platinum (Pt), calcium (Ca), ytterbium (Yb), aluminum (Al), copper (Cu), titanium (Ti), tantalum (Ta), rubidium (Ru), tungsten (W), molybdenum (Mo), nickel (Ni), tin (Sn), palladium (Pd), lead (Pb), and cobalt (Co), but is not limited thereto. In the present specification, the metal nitride may include one or more selected from the group consisting of titanium nitride (TiN), titanium aluminum nitride (TiAIN), tantalum silicon nitride (TaSiN), and rubidium titanium nitride (RuTiN), but is not limited thereto. In the present specification, the metal silicide may include one or more selected from the group consisting of titanium silicide (TiSi), tantalum silicide (TaSi), nickel silicide (NiSi), and cobalt silicide (CoSi), but is not limited thereto. In the present specification, the metal oxide may include one or more selected from the group consisting of gold oxide (AuOx), platinum oxide (PtOx), silver oxide (AgOx), palladium oxide (PdOx), iridium oxide (IrOx), and rubidium oxide (RuOx), but is not limited thereto.

The gate electrode 120 according to an example embodiment of the present disclosure may be disposed on the channel layer 160.

Referring to FIG. 1, in one example, the gate electrode 120 may surround at least a portion of the channel layer 160. In one example, there may be a plurality of gate electrodes 120, and adjacent gate electrodes 120 may be spaced apart from each other based on the second direction D2.

The memory device 100 according to an example embodiment of the present disclosure may include an insulating layer 110.

Referring to FIG. 1, in one example, the insulating layer 110 may surround at least a portion of the channel layer 160. In one example, the insulating layer 110 may include an insulating material. In the present specification, the insulating material may include one or more selected from the group consisting of silicon oxide, silicon nitride, silicon oxynitride, low-k materials, and high-k materials, but is not limited thereto. In the present specification, the low-k material may have a permittivity less than 3.9, and may include, for example, one or more from the group consisting of fluorinated tetraethylorthosilicate (FTEOS), hydrogen silsesquioxane (HSQ), Bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica, but is not limited thereto. In the present specification, the high-k material may have a permittivity of 3.9 or higher, and may include, for example, one or more from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but is not limited thereto.

There may be a plurality of insulating layers 110 according to the example embodiment of the present disclosure, and adjacent insulating layers 110 may be spaced apart from each other based on the second direction D2. In one example, the insulating layer 110 may be disposed so that a space between adjacent gate electrodes 120 is filled with the insulating layer. In one example, the insulating layer 110 may overlap the gate electrode 120 at least in a partial region when viewed in the second direction D2.

Referring to FIG. 1 in one example, the insulating layer 110 and the gate electrode 120 may have a structure in which they are alternately stacked, and the insulating layer 110 and the gate electrode 120 may be in contact with each other based on the second direction D2. Referring to FIG. 2, the insulating layer 110 may surround at least a portion of the channel layer 160. Referring to FIG. 3, the gate electrode 120 may surround at least a portion of the channel layer 160.

The channel layer 160 according to an example embodiment of the present disclosure may be disposed on the surface 101S of the substrate.

Referring to FIG. 1, in one example, the channel layer 160 may extend along the second direction D2. In one example, the gate electrode 120 may surround at least a portion of the channel layer 160.

The channel layer 160 according to an example embodiment of the present disclosure may include a semiconductor oxide. In one example, the channel layer 160 may be a semiconductor oxide and include an oxide including one or more selected from the group consisting of tantalum (Ta), hafnium (Hf), aluminum (Al), zinc (Zn), tungsten (W), vanadium (V), titanium (Ti), neodymium (Nb), silicon (Si), germanium (Ge), arsenic (As), tellurium (Te), antimony (Sb), gallium (Ga), indium (In), zirconium (Zr), tin (Sn), and nickel (Ni). In one example, the channel layer 160 may include one or more selected from the group consisting of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), zinc oxide (ZnO), tungsten oxide (WO), indium gallium silicon oxide (IGSO), indium oxide (InO), tin oxide (SnO), titanium oxide (TiO), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO), but is not limited thereto. In one example, in some cases, the channel layer 160 may include oxygen vacancies.

The electro-chemical layer 140 according to an example embodiment of the present disclosure may be disposed between the channel layer 160 and the gate electrode 120. In one example, the electro-chemical layer 140 may include oxygen vacancies. In one example, the electro-chemical layer 140 may receive oxygen vacancies from the channel layer 160 or transfer oxygen vacancies to the channel layer 160 depending on the voltage applied to the gate electrode 120. That is, the electro-chemical layer 140 may include oxygen vacancies to be transferred to the channel layer 160 or oxygen vacancies transferred from the channel layer 160 depending on the voltage applied to the gate electrode 120. In the present specification, the movement of oxygen vacancies may be performed in the opposite direction to the movement of oxygen ions, and the ions present in the channel layer 160 may be, for example, oxygen ions. In some example embodiments, the electro-chemical layer 140 may exchange oxygen vacancies with the channel layer 160, and change the electrical conductivity and a threshold voltage Vₜₕ of the channel layer 160 depending on the degree of exchange of oxygen vacancies.

The electro-chemical layer 140 according to an example embodiment of the present disclosure may include oxygen vacancies. A concentration of oxygen vacancies in the electro-chemical layer 140 according to an example embodiment of the present disclosure may be, for example, more than 10%, 10.5% or more, 11% or more, 11.5% or more, 12% or more, 12.5% or more, 13% or more, 13.5% or more, 14% or more, 14.5% or more, or 15% or more.

The concentration of oxygen vacancies in the electro-chemical layer 140 according to an example embodiment of the present disclosure may be, for example, 50% or less, 49% or less, 48% or less, 47% or less, 46% or less, 45% or less, 44% or less, 43% or less, 42% or less, 41% or less, 40% or less, 39% or less, 38% or less, 37% or less, 36% or less, or 35% or less, but is not limited thereto.

The electro-chemical layer 140 according to the example embodiment of the present disclosure may include metal oxide having a metal element (M)-oxygen (O) bond. In some example embodiments, the metal oxide included in the electro-chemical layer 140 may include one or more of a single metal oxide in which one metal element (M) and oxygen (O) are bonded of a composite metal oxide in which two or more metal elements (M) and oxygen (O) are bonded.

In one example, the metal element M may include one or more selected from the group consisting of transition metal elements TM of groups 3 to 6, but is not limited thereto. In one example, the transition metal element may include a group 3 transition metal element such as scandium (Sc), iridium (Y), or lanthanum (La), but is not limited thereto. In one example, the transition metal element may include a group 4 transition metal element such as titanium (Ti), zirconium (Zr), hafnium (Hf), or rutherfordium (Rf), but is not limited thereto. In one example, the transition metal element may include a group 5 transition metal element such as vanadium (V) or tantalum (Ta), but is not limited thereto. In one example, the transition metal element may include a group 6 transition metal element such as chromium (Cr), molybdenum (Mo), or tungsten (W), but is not limited thereto. In one example, the metal element M may include a group 4 transition metal element TM, for example, the group 4 transition metal element TM may include hafnium (Hf).

In the present specification, the concentration of oxygen vacancies for the metal oxide may be calculated, for example, according to the following equation 1, but is not limited thereto.

$$Concentration of oxygen vacanies ( \% ) = \frac{( M \times {n}_{M} - {O}_{b} )}{( M \times {n}_{M} )} \times 100 ( \% ) \qquad [ Equation 1 ]$$

In Equation 1, M represents the number of metal elements included in the metal oxide, n represents a value obtained by dividing the valency of the metal element included in the metal oxide by 2, and O_{b} represents the number of oxygen atoms bonded with the metal element in the metal oxide. In Equation 1, M and O_{b} may represent the number for the all metal oxides in the electro-chemical layer 140.

In the memory device 100 according to an example embodiment of the present disclosure, a) the metal element M is the group 3 transition metal element, and a ratio (O_{b3}/TM₃) of the number O_{b3} of oxygen atoms bonded to the group 3 transition metal elements and the number TM₃ of group 3 transition metals may be less than 1.35. In one example, in the memory device 100, b) the metal element M is the group 4 transition metal element, and a ratio (O_{b4}/TM₄) of the number O_{b4} of oxygen atoms bonded to the group 4 transition metal elements TM₄ and the number TM₄ of group 4 transition metals may be less than 1.8. In one example, in the memory device 100, c) the metal element M is the group 5 transition metal element, and a ratio (O_{b5}/TM₅) of the number O_{b5} of oxygen atoms bonded to the group 5 transition metal elements and the number TM₅ of group 5 transition metals may be less than 2.25. In one example, in the memory device 100, d) the metal element M is the group 6 transition metal element, and a ratio (O_{b6}/TM₆) of the number O_{b6} of oxygen atoms bonded to the group 6 transition metal elements and the number TM₆ of group 6 transition metals may be less than 2.7. In one example, the memory device may satisfy at least one of a) to d) described above.

In the memory device 100 according to an example embodiment of the present disclosure, a) the metal element M is a group 3 transition metal element, and the ratio (O_{b3}/TM₃) of the number O_{b3} of oxygen atoms bonded to the group 3 transition metal elements and the number TM₃ of group 3 transition metals may be 0.75 or more. In one example, in the memory device 100, b) the metal element M is the group 4 transition metal element, and the ratio (O_{b4}/TM₄) of the number O_{b4} of oxygen atoms bonded to the group 4 transition metal elements TM₄ and the number TM₄ of group 4 transition metals may be 1.8 or more. In one example, in the memory device 100, c) the metal element M is the group 5 transition metal element, and the ratio (O_{b5}/TM₅) of the number O_{b5} of oxygen atoms bonded to the group 5 transition metal elements and the number TM₅ of group 5 transition metals may be 1.25 or more. In one example, in the memory device 100, d) the metal element M is the group 6 transition metal element, and the ratio (O_{b6}/TM₆) of the number O_{b6} of oxygen atoms bonded to the group 6 transition metal elements and the number TM₆ of group 6 transition metals may be 1.5 or more. In one example, the memory device may satisfy at least one of a) to d) described above.

In one example, when a positive voltage is applied to the gate electrode 120, oxygen vacancies present in the electro-chemical layer 140 may be transferred to the channel layer 160. In one example, when a negative voltage is applied to the gate electrode 120, oxygen vacancies present in the channel layer 160 may be transferred to the electro-chemical layer 140. Through the process, the electro-chemical layer 140 may exchange oxygen vacancies with the channel layer 160, thereby changing the electrical conductivity and/or the threshold voltage Vₜₕ of the channel layer 160 depending on the degree of exchange of oxygen vacancies.

The gate oxide layer 130 according to an example embodiment of the present disclosure may be disposed between the gate electrode 120 and the electro-chemical layer 140. In one example, the gate oxide layer 130 may include one or more selected from the group consisting of metal oxide, silicon oxide, silicon nitride, silicon oxynitride, a low-k material, and a high-k material, but is not limited thereto. In one example, the metal oxide may include one or more selected from the group consisting of, for example, aluminum oxide (AlO) and tin oxide (SnO).

The memory device 100 according to an example embodiment of the present disclosure may include a source electrode 200 and a drain electrode 300. In one example, the channel layer 160 may be electrically connected to a source and a drain.

In one example, referring to FIG. 1, the source electrode 200 and the drain electrode 300 may be spaced apart from each other based on the second direction D2. In one example, the source electrode 200 and the drain electrode 300 may each independently include a conductive material.

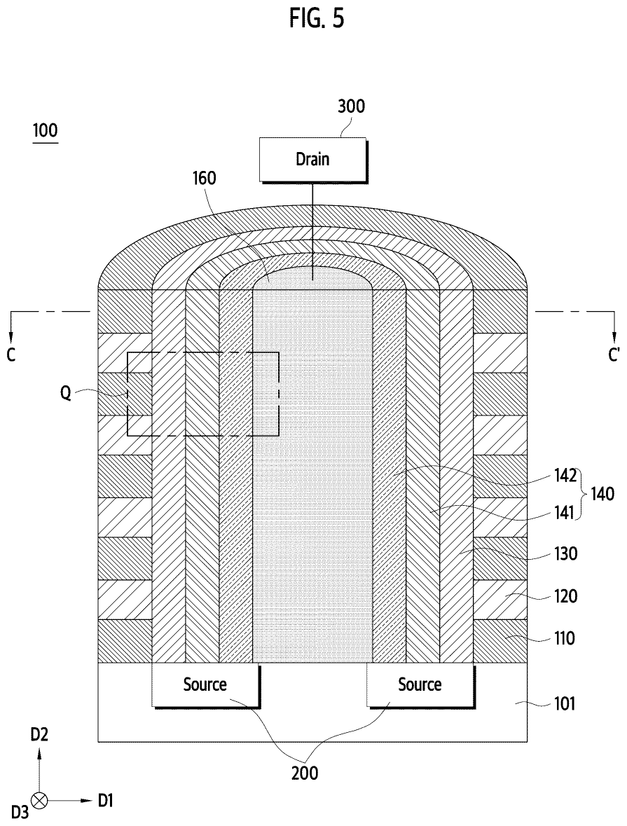

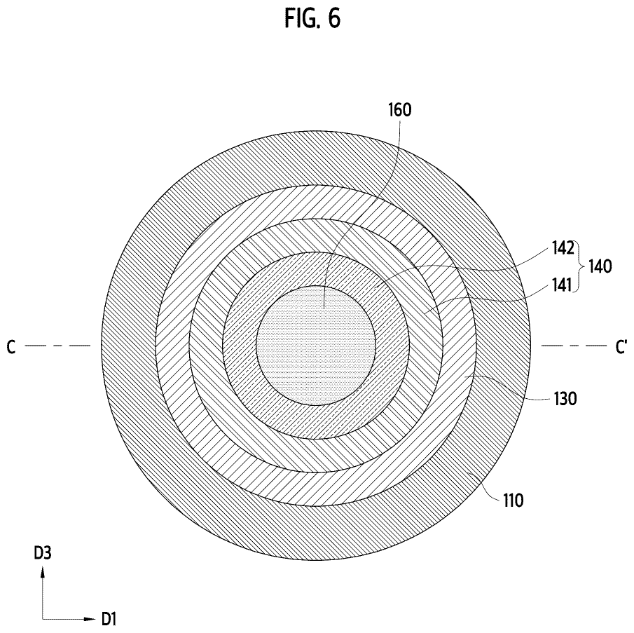

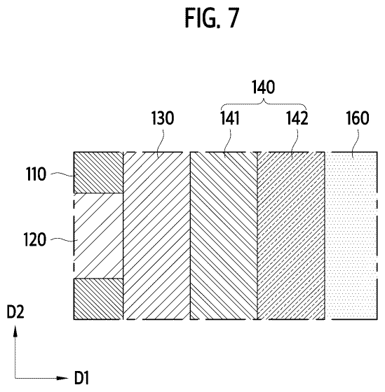

FIG. 5 schematically illustrates at least a portion of an electro-chemical memory device 100 according to an example embodiment of the present disclosure. FIG. 6 illustrates a cross-section taken along CC′ of FIG. 5. FIG. 7 is an enlarged view of part Q in FIG. 5.

An electro-chemical layer 140 according to the example embodiment of the present disclosure may include one or more of a reservoir layer 141 and an electrolyte layer 142. In one example, the electro-chemical layer 140 may include the reservoir layer 141 and the electrolyte layer 142 disposed to be further away from a gate electrode 120 than the reservoir layer 141. In one example, the contents of the reservoir layer 141 and the electrolyte layer 142 may refer to the description of the electro-chemical layer 140 unless contradictory.

For example, in some cases, the reservoir layer 141 may include oxygen vacancies. The concentration of oxygen vacancies in the reservoir layer 141 may be, for example, more than 10%, 10.5% or more, 11% or more, 11.5% or more, 12% or more, 12.5% or more, 13% or more, 13.5% or more, 14% or more, 14.5% or more, or 15% or more, and may be 50% or less, 49% or less, 48% or less, 47% or less, 46% or less, 45% or less, 44% or less, 43% or less, 42% or less, 41% or less, 40% or less, 39% or less, 38% or less, 37% or less, 36% or less, or 35% or less, but is not limited thereto.

In one example, when a positive voltage is applied to the gate electrode 120, oxygen vacancies present in the reservoir layer 141 may be transferred to the channel layer 160. In one example, when a negative voltage is applied to the gate electrode 120, oxygen vacancies present in the channel layer 160 may be transferred to the reservoir layer 141. Through the process, the reservoir layer 141 may exchange oxygen vacancies with the channel layer 160, thereby changing the electrical conductivity and/or the threshold voltage Vₜₕ of the channel layer 160 depending on the degree of exchange of oxygen vacancies.

In one example, the electrolyte layer 142 may pass oxygen vacancies therethrough such that oxygen vacancies are transferred from the channel layer 160 to the reservoir layer 141 or oxygen vacancies are smoothly transferred from the reservoir layer 141 to the channel layer 160 depending on the voltage applied to the gate electrode 120. That is, the electrolyte layer 142 may allow oxygen vacancies transferred from the reservoir layer 141 to the channel layer 160 or transferred from the channel layer 160 to the reservoir layer 141 depending on the voltage applied to the gate electrode 120 to pass therethrough. In one example, the electrolyte layer 142 may allow the channel layer 160 and the reservoir layer 141 to smoothly exchange oxygen vacancies with each other, thereby changing the electrical conductivity and/or the threshold voltage Vₜₕ of the channel layer 160 depending on the degree of exchange of oxygen vacancies.

The concentration of oxygen vacancies in the reservoir layer 141 according to an example embodiment of the present disclosure may be higher than the concentration of oxygen vacancies in the electrolyte layer 142. Thereby, the oxygen vacancies of the reservoir layer 141 may be smoothly transferred through the electrolyte layer 142 to the channel layer 160.

The thickness of the electrolyte layer 142 according to an example embodiment of the present disclosure may be thinner than the thickness of the reservoir layer 141. Thereby, oxygen vacancies may more easily move from the electrolyte layer 142 to the reservoir layer 141 and to the channel layer 160.

In one example, the reservoir layer 141 and the electrolyte layer 142 may each independently include metal oxide having the aforementioned metal element (M)-oxygen (O) bond. The metal oxide included in the reservoir layer 141 and the metal oxide included in the electrolyte layer 142 may be different from each other. For example, the metal element M included in the electrolyte layer 142 may include one or more selected from a group of metal elements consisting of cerium (Ce), gallium (Ga), nickel (Ni), aluminum (Al), zinc (Zn), arsenic (As), tellurium (Te), antimony (Sb), indium (In), and tin (Sn), in addition to the metals listed in the electro-chemical layer 140, but is not limited thereto. In one example, the metal oxide included in the electrolyte layer 142 may include one or more selected from the group consisting of hafnium oxide, cerium oxide, tantalum oxide, gallium oxide, nickel oxide, and aluminum oxide.

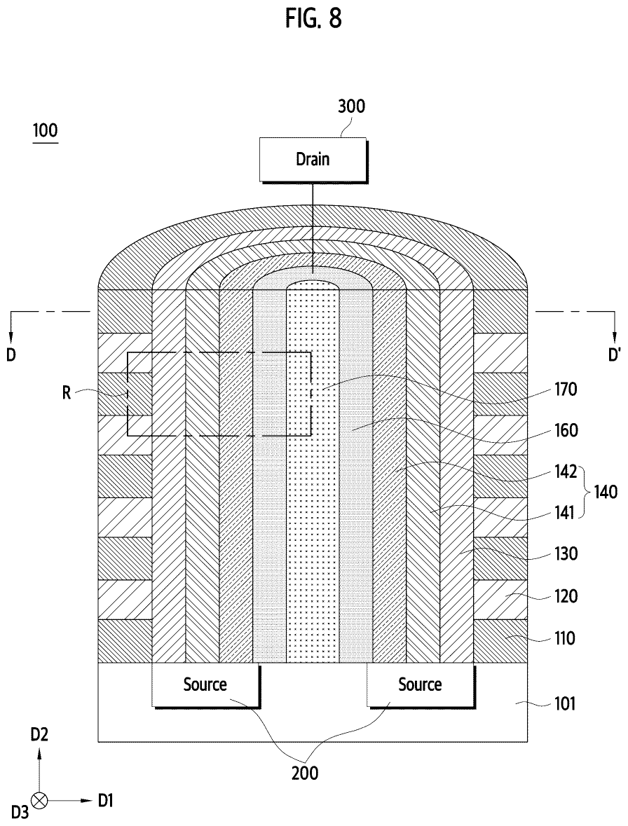

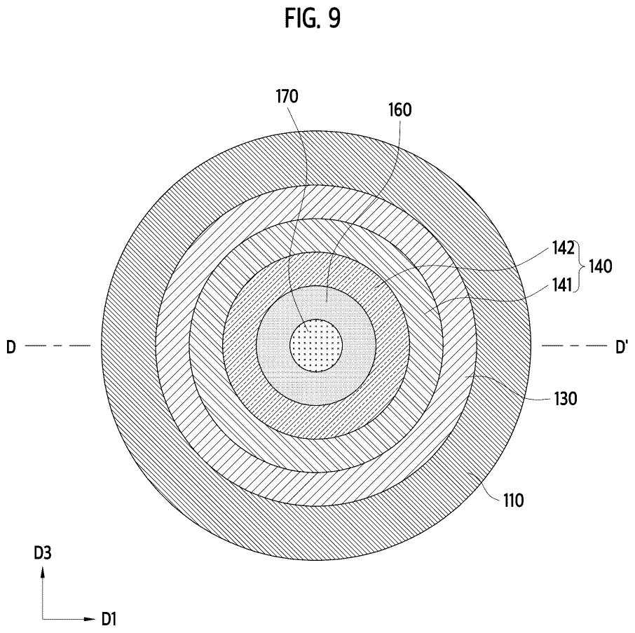

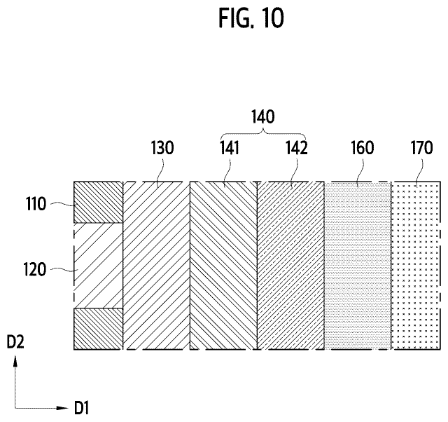

FIG. 8 schematically illustrates at least a portion of a memory device 100 according to an example embodiment of the present disclosure. FIG. 9 illustrates a cross-section taken along DD′ of FIG. 8. FIG. 10 is an enlarged view of part R in FIG. 8.

The memory device 100 according to an example embodiment of the present disclosure may include a filling layer 170 surrounded by a channel layer 160. In one example, a filling layer 170 may include an insulating material. In some cases, the filling layer 170 may include air.

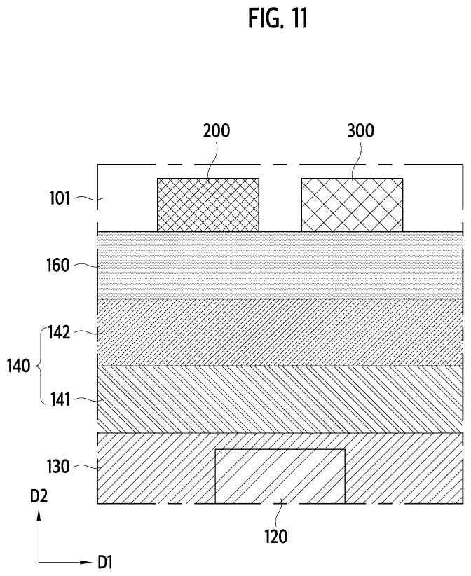

FIG. 11 schematically illustrates at least a portion of a memory device according to an example embodiment of the present disclosure. Unlike the memory devices 100 illustrated in FIGS. 1 to 10, a memory device 100 illustrated in FIG. 11 may have a channel layer 160 and a substrate 101 disposed parallel to each other. Hereinafter, the content of FIG. 11 may refer to the description of FIGS. 1 to 10 unless contradictory.

The gate electrode 120 according to an example embodiment of the present disclosure may be disposed between the substrate 101 and the channel layer 160 as described above.

Referring to FIG. 11, in one example, the gate electrode 120 may be disposed parallel to at least a portion of the channel layer 160. In one example, the channel layer 160 may be disposed parallel to the substrate 101. In one example, the channel layer 160 may be disposed parallel to the substrate 101 along the first direction D1.

Referring to FIG. 11, the memory device 100 according to an example embodiment of the present disclosure may include a source electrode 200 and a drain electrode 300. In one example, the source electrode 200 and the drain electrode 300 may be spaced apart from each other based on the first direction D1. For example, the source electrode 200 and the drain electrode 300 may be disposed on the channel layer 160 or inside the substrate 101.

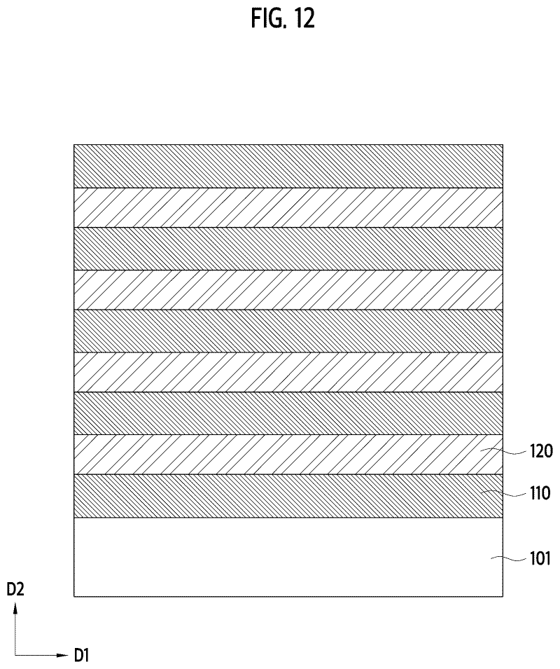

FIGS. 12 to 16 are views for describing a method of manufacturing the memory device 100 according to an example embodiment of the present disclosure. Hereinafter, the description of the method of manufacturing the memory device 100 may refer to the above-described contents described through FIGS. 1 to 11, unless contradictory. Hereinafter, the method of manufacturing the memory device 100 in which a channel layer 160 is formed by extending along a second direction intersecting a first direction parallel to the surface of the substrate 101 is described, but this is only for convenience of description and the method is not limited thereto.

Referring to FIG. 12, in one example, the method of manufacturing the memory device 100 may include forming a stacked body by alternating the gate electrodes 120 and the insulating layers 110 on the substrate 101. The insulating layer 110 closest to the substrate 101 may be closer to the substrate 101 than the gate electrode 120 closest to the substrate 101. In some example embodiments, the gate electrode 120 closest to the substrate 101 may be closer to the substrate 101 than the insulating layer 110 closest to the substrate 101. In one example, the stacked body of the gate electrode 120 and the insulating layer 110 may be formed through deposition. In the present specification, deposition may be performed through various methods such as chemical vapor deposition (CVD), physical vapor deposition (PVD), atomic layer deposition (ALD), or the like. The components of the memory device 100 may be formed, for example, through deposition, unless otherwise specified, but example embodiments are not limited thereto.

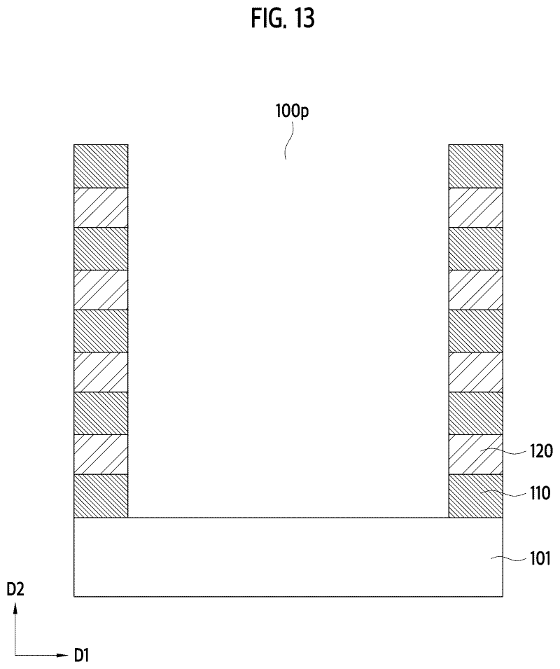

Referring to FIG. 13, in one example, the method of manufacturing the memory device 100 may include removing a portion of the stacked body of the gate electrode 120 and the insulating layer 110 to form a columnar-shaped empty space 100p. There may be one or two or more empty spaces 100p, and in the case of two or more, each empty space 100p may be formed to be spaced apart from each other in the first direction D1 and the third direction. The stacked body may be removed, for example, by an etching process.

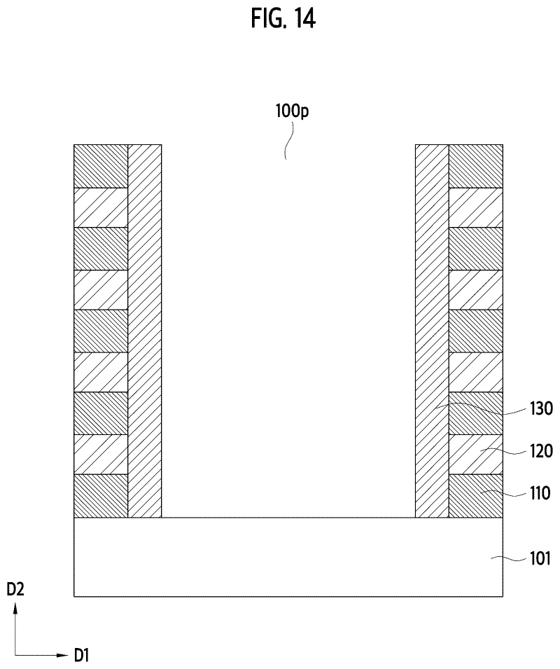

Referring to FIG. 14, in one example, the method of manufacturing the memory device 100 may include forming the gate oxide layer 130 on the gate electrode 120. In one example, the forming of the gate oxide layer 130 may be achieved by forming the gate oxide layer 130 on a surface (e.g., at a boundary) of a columnar-shaped empty space 100p. In one example, the gate oxide layer 130 may be formed on the gate electrode 120 and, at the same time, on the insulating layer 110. That is, in one example, the method of manufacturing the memory device 100 may include forming the gate oxide layer 130 that contacts at least a portion of each of the gate electrode 120 and the insulating layer 110.

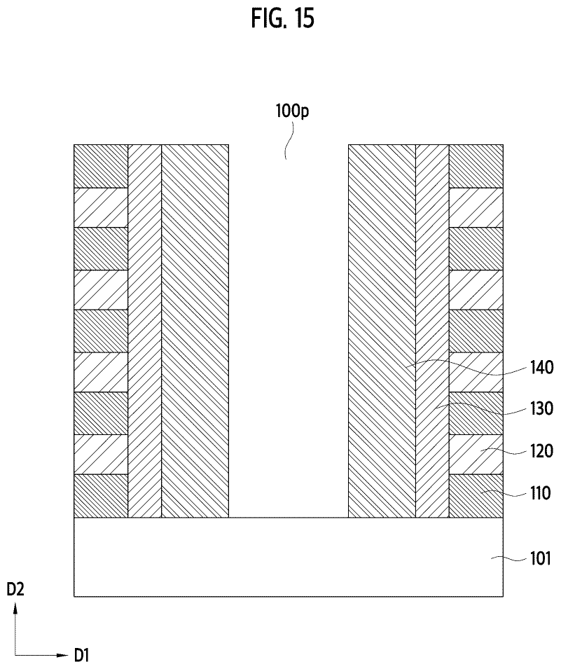

Referring to FIG. 15, in one example, the method of manufacturing the memory device 100 may include forming the electro-chemical layer 140 on the gate oxide layer 130. In one example, the electro-chemical layer 140 may be formed along a profile of the gate oxide layer 130. In one example, when the electro-chemical layer 140 includes both the reservoir layer 141 and the electrolyte layer 142, the forming of the electro-chemical layer 140 may include forming the reservoir layer 141 and then forming the electrolyte layer 142.

In one example, the forming of the electro-chemical layer 140 may include depositing a metal precursor. In one example, the depositing of the metal precursor may be performed by chemical vapor deposition (CVD), physical vapor deposition (PVD), or atomic layer deposition (ALD), but is not limited thereto.

In one example, the depositing of the metal precursor may be performed at a temperature of less than 200° C., less than or equal to 190° C., less than or equal to 180° C., less than or equal to 170° C., less than or equal to 160° C., or less than or equal to 150° C. By performing the deposition at the temperatures described above, the electro-chemical layer 140 may have a relatively low oxygen-to metal ratio and a relatively high concentration of oxygen vacancies while reducing or minimizing the content of impurities (carbon and the like) derived from the metal precursor. Thereby, a memory window (M.W.) of the memory device 100 may be improved.

In one example, the metal precursor may include tetrakis(ethylmethylamido)hafnium (TEMAHf). By using the metal precursor, the metal precursor is partially decomposed even when the deposition is performed at a relatively low temperature of less than 200° C., thereby making it possible to easily deposit the electro-chemical layer, and in addition, providing a memory device having a relatively low oxygen-to-metal ratio and a relatively high oxygen vacancy concentration while reducing or minimizing the content of impurities (carbon and the like) derived from the metal precursor in the electro-chemical layer.

In one example, a thermal decomposition temperature of the metal precursor may be less than 200° C., less than or equal to 190° C., less than or equal to 180° C., less than or equal to 170° C., less than or equal to 160° C., or less than or equal to 150° C., but is not limited thereto. The thermal decomposition temperature may be measured, for example, by thermogravimetric analysis (TGA).

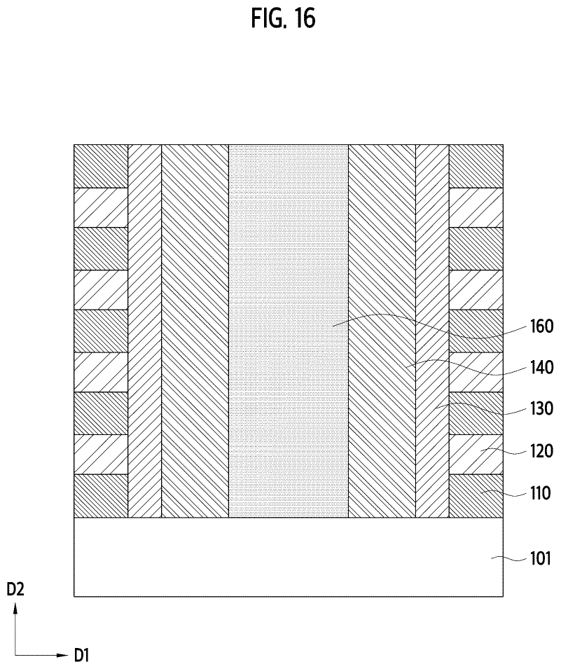

Referring to FIG. 16, in one example, the method of manufacturing the memory device 100 may include forming the channel layer 160 on the electro-chemical layer 140. In one example, the channel layer 160 may be formed along a profile of the electro-chemical layer 140. In one example, the channel layer 160 may fill the entire columnar-shaped empty space 100p. In one example, although not illustrated, the channel layer 160 may be formed to fill a portion of the columnar-shaped empty space 100p, and in addition, the filling layer 170 may be formed to fill the entire columnar-shaped empty space 100p.

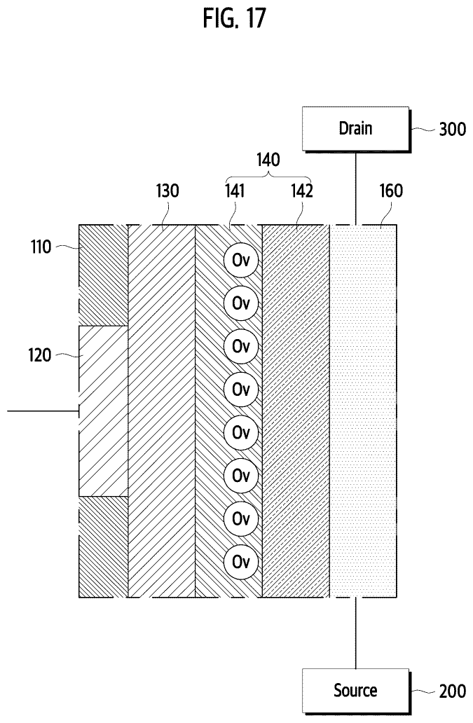

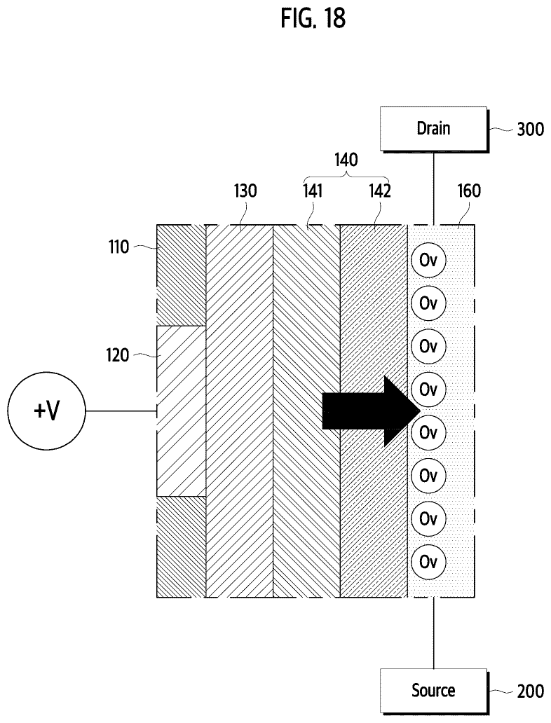

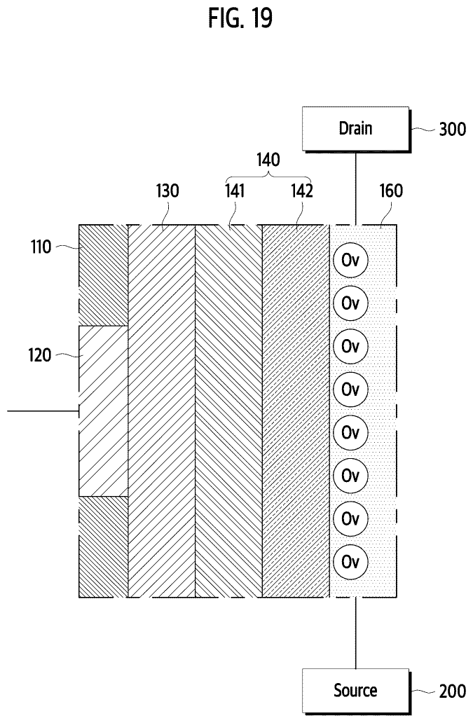

FIGS. 17 to 20 schematically illustrate at least a portion of the memory device 100 to describe a method of driving the memory device 100 according to an example embodiment of the present disclosure.

In the method of driving the memory device 100 according to an example embodiment of the present disclosure, when a voltage is applied to the gate electrode 120, the channel layer 160 and the electro-chemical layer 140 may exchange oxygen vacancies Ov with each other.

In one example, when a voltage is applied to the gate electrode 120, oxygen vacancies Ov present in the electro-chemical layer 140 may be transferred to the channel layer 160, or oxygen vacancies Ov present in the channel layer 160 may be transferred to the electro-chemical layer 140. Thereby, the electrical conductivity and/or the threshold voltage Vₜₕ of the channel layer 160 may be changed from the electrical conductivity and/or the threshold voltage Vₜₕ of the channel layer 160 before the voltage is applied to the gate electrode 120, respectively.

In one example, when the electro-chemical layer 140 includes the reservoir layer 141 and the electrolyte layer 142, the reservoir layer 141 may be operated in the same manner as the driving principle of the electro-chemical layer 140 described above when a voltage is applied to the gate electrode 120. The electrolyte layer 142 may allow oxygen vacancies Ov to pass therethrough such that the oxygen vacancies Ov may be smoothly transferred from the channel layer 160 to the reservoir layer 141 or such that oxygen vacancies may be smoothly transferred from the reservoir layer 141 to the channel layer 160.

In one example, when a voltage is applied to the gate electrode 120, the gate oxide layer 130 may allow the electro-chemical layer 140 to smoothly exchange the oxygen vacancies Ov with the channel layer 160, and block or prevent the oxygen vacancies Ov present in the electro-chemical layer 140 from being transferred to the gate electrode 120.

In one example, the method of driving the memory device 100 may include transferring the oxygen vacancies Ov present in the electro-chemical layer 140 to the channel layer 160 or transferring the oxygen vacancies Ov present in the channel layer 160 to the electro-chemical layer 140, when a voltage is applied to a gate electrode 120. In this case, the electrical conductivity and/or the threshold voltage Vₜₕ of the channel layer 160 may be changed from those before the voltage is applied to the gate electrode 120, respectively, and as the electrical conductivity and/or the threshold voltage Vₜₕ of the channel layer 160 are different, the method of driving the memory device 100 may include performing a write (or program) or erase operation.

In one example, the method of driving the memory device 100 may include transferring, by the electro-chemical layer 140, oxygen vacancies Ov to the channel layer 160 and performing, by the channel layer 160, the write operation by which the electrical conductivity is increased, when a positive voltage is applied to the gate electrode 120. Here, the method of driving the memory device 100 may include transferring, by the channel layer 160, the oxygen vacancies Ov to the electro-chemical layer 140 and performing the erase operation by which the electrical conductivity of the channel layer 160 is decreased as the oxygen vacancies Ov present in the channel layer 160 are restored to the electro-chemical layer 140, when a voltage is changed from positive to negative and the changed voltage is applied to the gate electrode 120.

In one example, the method of driving the memory device 100 may include transferring, by the channel layer 160, the oxygen vacancies Ov to the electro-chemical layer 140 and performing, by the channel layer 160, the write operation by which the electrical conductivity is decreased, when a negative voltage is applied to the gate electrode 120. Here, the method of driving the memory device 100 may include transferring, by the electro-chemical layer 140, the oxygen vacancies Ov to the channel layer 160 and performing the erase operation by which the electrical conductivity of the channel layer 160 is increased as the oxygen vacancies Ov present in the electro-chemical layer 140 are restored to the channel layer 160, when a voltage is changed from negative to positive and the changed voltage is applied to the gate electrode 120.

In one example, the method of driving the memory device 100 may include performing the write or erase operation as the threshold voltage Vₜₕ is changed when the voltage is applied to the gate electrode 120. In one example, the threshold voltage Vₜₕ of the channel layer 160 may be changed as the electrical conductivity of the channel layer 160 changes. When the positive voltage is applied to the gate electrode 120, the threshold voltage Vₜₕ may decrease.

In one example, the method of driving the memory device 100 may include performing a read operation to check a degree of inclusion of oxygen vacancies Ov (that is, the state of data) through the electrical conductivity of the channel layer 160 by applying a voltage to the gate electrode 120. Here, it may be desirable that the voltage applied to the gate electrode 120 is low enough so that movement of the oxygen vacancies Ov does not occur. In addition, in one example, the degree of inclusion of the oxygen vacancies Ov present in the channel layer 160 may be measured as resistance through a current-voltage curve as well as the electrical conductivity of the channel layer 160, through which the read operation may be performed.

Hereinafter, some example embodiments of the present application are further described with reference to specific examples. The examples and comparative examples are intended to illustrate the present application only and not to limit the scope of the appended claims. It will be apparent to those skilled in the art that various changes and modifications to the examples are possible within the scope and technical idea of the present application. Such variations and modifications should be included in the scope of the appended claims.

### Example 1

A memory device 100 having a structure as in FIG. 5 was manufactured, which includes a channel layer 160 including Indium Gallium Zinc Oxide (IGZO), a reservoir layer 141 of an electro-chemical layer 140 including hafnium oxide, and a gate oxide layer 130 including aluminum oxide (II) (AlO), where the thickness of the electro-chemical layer 140 including the reservoir layer 141 is about 8 nm and the thickness of the gate oxide layer 130 is about 10 nm. The electro-chemical layer 140 and the gate oxide layer 130 were formed using the atomic layer deposition (ALD) method. In this case, when the electro-chemical layer 140 is formed, atomic layer deposition was performed at about 50° C., TEMAHf was used as a metal precursor, and water vapor (H₂O) was used as a reaction gas.

### Example 2

A memory device was manufactured in the same manner as in Example 1 described above, except that atomic layer deposition was performed at about 100° C. when forming the electro-chemical layer 140.

### Comparative Example 1

A memory device was manufactured in the same manner as in Example 1 described above, except that atomic layer deposition was performed at about 200° C. when forming the electro-chemical layer 140.

### Comparative Example 2

A memory device was manufactured in the same manner as in Example 1 described above, except that atomic layer deposition was performed at about 300° C. when forming the electro-chemical layer 140, Tris(dimethylamido)cyclopentadienyl Hafnium (ACP3) was used as a metal precursor, and ozone (O₃) was used as a reaction gas.

### Evaluation 1—Memory Window (M.W.) Measurement

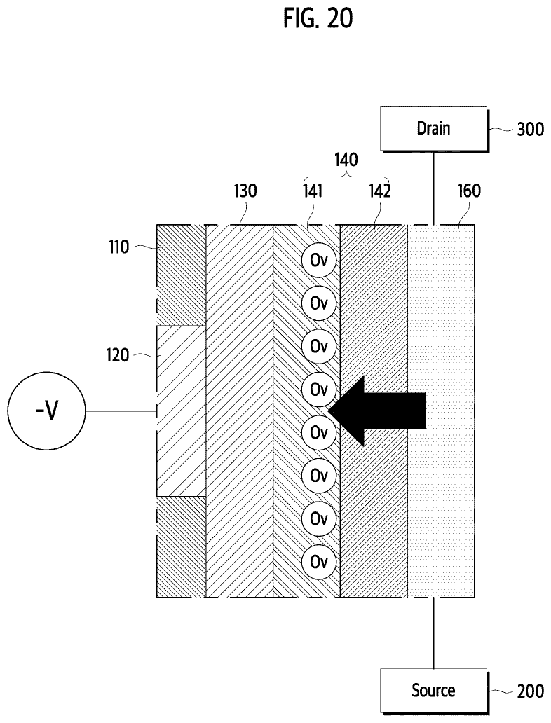

The characteristics of a drain-source current I_{DS} with respect to a gate-source voltage V_{gs} (−12 V to +12 V) of the memory devices 100 of Example 1, Example 2, and Comparative Example 1 were measured. After performing one voltage sweep from −12 V→+12 V→−12 V, a graph was created and shown in FIG. 20 and Table 1.

TABLE 1

| | | | Comparative |
|---|---|---|---|
| Classification | Example 1 | Example 2 | Example 1 |
| Deposition | About 50 | About 100 | About 200 |
| temperature (° C.) | | | |
| Memory Window (V) | Up to about 11 | Up to about 7 | Up to about 4 |

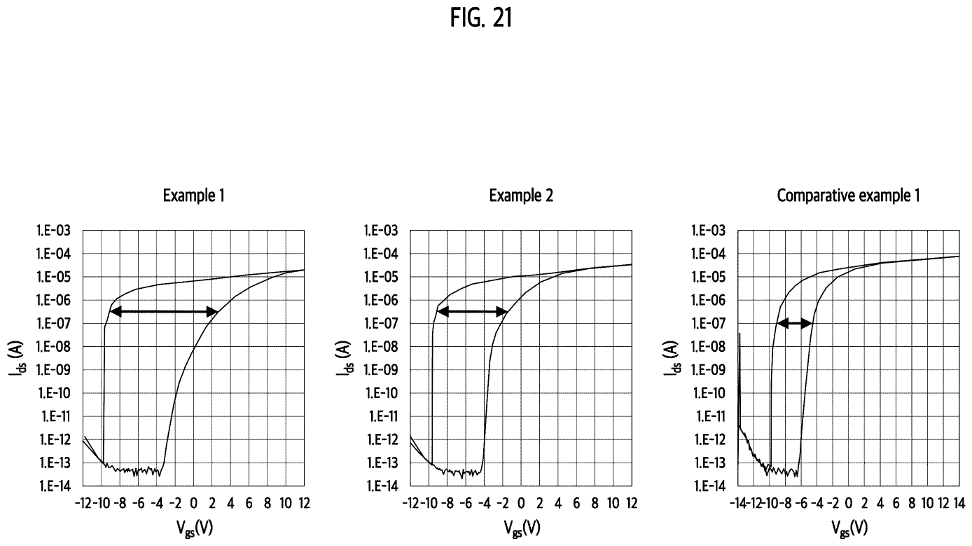

Referring to FIG. 21 and Table 1, it may be confirmed that the difference in I_{ds} for V_{gs} when the voltage increases and when the voltage decreases (e.g., the memory window) is relatively large in Example 1 and Example 2 compared to Comparative Example 1.

### Evaluation 2-Measurement of Impurity (Carbon) Content and Oxygen Vacancy Concentration

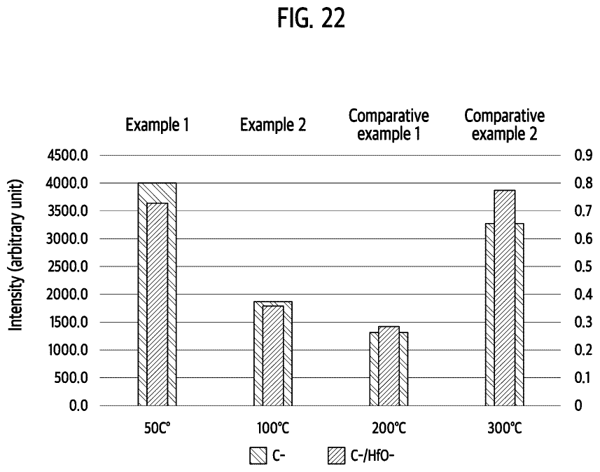

FIG. 22 shows the results of analyzing the carbon content (C) and the carbon content for hafnium (C/Hf) in the memory devices 100 of Example 1, Example 2, Comparative Example 1 and Comparative Example 2, using a secondary ion mass spectrometer (SIPMS). Carbon is an impurity derived from the precursor used in the deposition process.

Referring to FIG. 22, it may be confirmed that the impurity contents of Example 1 and Example 2 are at similar levels to the impurity contents of Comparative Example 2 and Comparative Example 1, respectively. By maintaining the impurity content below a certain range, the disadvantages in device behavior caused by impurities filling the spaces where oxygen vacancies may be reduced, thereby reducing the deterioration of endurance and/or retention caused by carbon impurities.

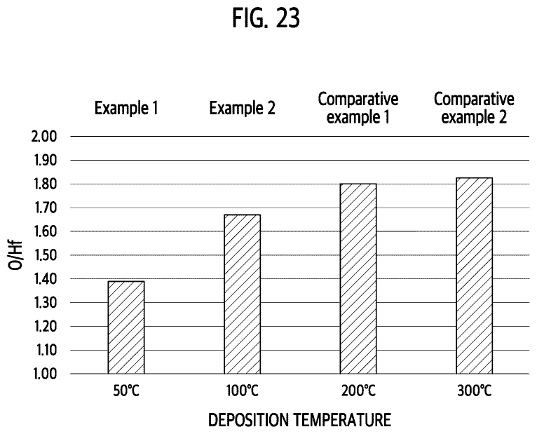

Meanwhile, results of calculating an O/Hf ratio, which is a ratio of oxygen to hafnium, by analyzing the memory devices 100 of Example 1, Example 2, Comparative Example 1, and Comparative Example 2 using X-ray photoelectron spectroscopy (XPS) are shown in FIG. 23 and Table 2.

TABLE 2

| | | | Comparative | Comparative |
|---|---|---|---|---|
| Classification | Example 1 | Example 2 | Example 1 | Example 2 |
| O/Hf | 1.39 | 1.67 | 1.80 | 1.83 |
| Oxygen vacancy | 30.7 | 16.5 | 9.9 | 8.7 |
| concentration (%) | | | | |

Referring to FIG. 23 and Table 2, it may be confirmed that Example 1 and Example 2 have lower O/Hf values than Comparative Example 1 and Comparative Example 2.

In summary, it may be confirmed that Example 1 and Example 2 have a lower ratio of oxygen to metal, a higher oxygen vacancy concentration, and a higher memory window than Comparative Example 1 and Comparative Example 2, even though they have similar levels of impurity contents.

Some example embodiments of the present disclosure can provide memory devices capable of implementing a memory function even when a relatively small voltage is applied to a gate electrode while improving integration density and/or a driving method of the memory device. In addition, some example embodiments of the present disclosure can provide a memory device with an improved memory window (M.W.) by increasing the movement of oxygen vacancies in the operating principle of an electro-chemical random-access memory device, and/or a method of driving the memory device.

Effects of the present disclosure are not limited to those mentioned above, and other effects not mentioned will be clearly understood by those skilled in the art from the description below.

The present disclosure is not limited to the above example embodiments and may be manufactured in various different forms and those of ordinary skill in the art to which the present disclosure pertains may understand that the additional or alternative example embodiments may be embodied in other specific forms without departing from the technical spirit or essential features of the present disclosure. Therefore, it is to be appreciated that the example embodiments described above are intended to be illustrative in all respects and not restrictive.

What is claimed is:

1. A memory device comprising:
a substrate;
a channel layer on a surface of the substrate, the channel layer including a semiconductor oxide;
a gate electrode on the channel layer;
an electro-chemical layer between the channel layer and the gate electrode; and
a gate oxide layer between the gate electrode and the electro-chemical layer,
wherein the electro-chemical layer has a concentration of oxygen vacancies exceeding 10% and is capable of transferring oxygen vacancies to the channel layer or receiving oxygen vacancies from the channel layer, depending on a voltage applied to the gate electrode.

2. The memory device of claim 1, wherein
a first direction refers to a direction parallel to the surface of the substrate,
the channel layer extends along a second direction intersecting the first direction,
the gate electrode surrounds at least a portion of the channel layer.

3. The memory device of claim 2, further comprising:
a source electrode and a drain electrode electrically connected to the channel layer,
wherein the source electrode and the drain electrode are spaced apart from each other based on the second direction.

4. The memory device of claim 2, further comprising:
an insulating layer overlapping the gate electrode in at least a partial region when viewed in the second direction, the insulating layer surrounding at least a portion of the channel layer.

5. The memory device of claim 4, wherein
the gate electrode includes a plurality of gate electrodes,
an adjacent pair of the plurality of gate electrodes are spaced apart from each other based on the second direction, and
the insulating layer fills a space between the adjacent pair of the plurality of gate electrodes.

6. The memory device of claim 1, wherein the channel layer is parallel to the substrate.

7. The memory device of claim 6, further comprising:
a source electrode and a drain electrode electrically connected to the channel layer,
wherein the source electrode and the drain electrode are spaced apart from each other based on a first direction parallel to the surface of the substrate.

8. The memory device of claim 1, wherein
the electro-chemical layer is capable of transferring the oxygen vacancies present therein to the channel layer when a positive voltage is applied to the gate electrode, and
the channel layer is capable of transferring the oxygen vacancies present therein to the electro-chemical layer when a negative voltage is applied to the gate electrode.

9. The memory device of claim 1, wherein
the electro-chemical layer includes a reservoir layer and an electrolyte layer, the reservoir layer being adjacent to the gate electrode and including oxygen vacancies, the electrolyte layer being adjacent to the channel layer,
the reservoir layer is capable of transferring the oxygen vacancies present therein to the channel layer when a positive voltage is applied to the gate electrode, and
the channel layer is capable of transferring the oxygen vacancies present therein to the reservoir layer when a negative voltage is applied to the gate electrode, and
the electrolyte layer is capable of allowing the oxygen vacancies to move between the channel layer and the reservoir layer, depending on the voltage applied to the gate electrode.

10. The memory device of claim 9, wherein a concentration of the oxygen vacancies included in the reservoir layer exceeds 10%.

11. The memory device of claim 9, wherein the reservoir layer and the electrolyte layer are in contact with each other at least in some region.

12. The memory device of claim 9, wherein a thickness of the electrolyte layer is thinner than a thickness of the reservoir layer.

13. The memory device of claim 1, wherein the electro-chemical layer includes metal oxide having a metal element (M)-oxygen (O) bond.

14. The memory device of claim 13, wherein the metal element (M) includes one or more selected from the group consisting of transition metal elements (TM) of groups 3 to 6.

15. The memory device of claim 14, wherein at least one of the following conditions a) to d) is satisfied:
a) the metal element (M) is a group 3 transition metal element, and a ratio (O_{b3}/TM₃) of a number (O_{b3}) of oxygen atoms bonded to the group 3 transition metal elements and a number (TM₃) of group 3 transition metals is less than 1.35;
b) the metal element (M) is a group 4 transition metal element, and a ratio (O_{b4}/TM₄) of a number (O_{b4}) of oxygen atoms bonded to the group 4 transition metal elements (TM₄) and a number (TM₄) of group 4 transition metals is less than 1.8;
c) the metal element (M) is a group 5 transition metal element, and a ratio (O_{b5}/TM₅) of a number (O_{b5}) of oxygen atoms bonded to the group 5 transition metal elements and a number (TM₅) of group 5 transition metals is less than 2.25; and
d) the metal element (M) is a group 6 transition metal element, and a ratio (O_{b6}/TM₆) of a number (O_{b6}) of oxygen atoms bonded to the group 6 transition metal elements and a number (TM₆) of group 6 transition metals is less than 2.7.

16. The memory device of claim 1, further comprising:
a filling layer surrounded by the channel layer,
wherein the filling layer includes an insulating material.

17. A method of driving a memory device, the memory device including a substrate, a channel layer on a surface of the substrate and including a semiconductor oxide, a gate electrode between the substrate and the channel layer, an electro-chemical layer between the channel layer and the gate electrode and including oxygen vacancies, the electro-chemical layer with a concentration of the oxygen vacancies exceeding 10%, and a gate oxide layer between the gate electrode and the electro-chemical layer, the method comprising:
transferring the oxygen vacancies present in the electro-chemical layer to the channel layer or transferring oxygen vacancies present in the channel layer to the electro-chemical layer when a voltage is applied to the gate electrode such that an electrical conductivity and a threshold voltage (Vₜₕ) of the channel layer change values different from the electrical conductivity and the threshold voltage (Vₜₕ) of the channel layer prior to the application of the voltage to the gate electrode; and
performing a write operation or an erase operation as the electrical conductivity and the threshold voltage of the channel layer change.

18. The method of claim 17, wherein
the write operation is performed to transfer the oxygen vacancies present in the electro-chemical layer to the channel layer by applying a positive voltage to the gate electrode so that the electrical conductivity of the channel layer increases or the threshold voltage (Vₜₕ) decreases compared to the electrical conductivity and the threshold voltage (Vₜₕ) of the channel layer prior to the application of the voltage to the gate electrode, or
the erase operation is performed to transfer the oxygen vacancies present in the channel layer to the electro-chemical layer by applying a negative voltage to the gate electrode so that the electrical conductivity of the channel layer decreases compared to the electrical conductivity and the threshold voltage (Vₜₕ) of the channel layer prior to the application of the voltage to the gate electrode.

19. The method of claim 17, further comprising:
performing a read operation to check a degree of inclusion of the oxygen vacancies through the electrical conductivity of the channel layer by applying the voltage to the gate electrode.

20. A memory device comprising:
a substrate, a surface of the substrate extending in a first direction;
a channel layer extending along a second direction intersecting the first direction, the channel layer including a semiconductor oxide;
a gate electrode surrounding at least a portion of the channel layer;
an insulating layer overlapping the gate electrode at least in a portion of a region when viewed in the second direction, the insulating layer surrounding at least a portion of the channel layer;
an electro-chemical layer between the channel layer and the gate electrode;
a gate oxide layer between the gate electrode and the electro-chemical layer; and
a source electrode electrically connected to the channel layer and a drain electrode spaced apart from the source electrode based on the first direction,
wherein the electro-chemical layer is capable of transferring oxygen vacancies present therein to the channel layer or receiving oxygen vacancies from the channel layer, depending on a voltage applied to the gate electrode,
a concentration of the oxygen vacancies included in the electro-chemical layer exceeds 10%,
the electro-chemical layer includes a reservoir layer and an electrolyte, the reservoir layer being adjacent to the gate electrode and including oxygen vacancies, the electrolyte layer being adjacent to the channel layer,
the reservoir layer is capable of transferring the oxygen vacancies present therein to the channel layer when a positive voltage is applied to the gate electrode and the channel layer is capable of transferring the oxygen vacancies present therein to the reservoir layer when a negative voltage is applied to the gate electrode,
the electrolyte layer is capable of allowing the oxygen vacancies to move between the channel layer and the reservoir layer, depending on the voltage applied to the gate electrode, the reservoir layer and the electrolyte layer each independently include metal oxide having a metal element (M)-oxygen (O) bond,
the metal element (M) includes at least one selected from the group consisting of transition metal elements (TM) of groups 3 to 6, and
at least one of the following conditions a) to d) is satisfied:
a) the metal element (M) is a group 3 transition metal element, and a ratio (O_{b3}/TM₃) of a number (O_{b3}) of oxygen atoms bonded to the group 3 transition metal elements and a number (TM₃) of group 3 transition metals is less than 1.35;
b) the metal element (M) is a group 4 transition metal element, and a ratio (O_{b4}/TM₄) of a number (O_{b4}) of oxygen atoms bonded to the group 4 transition metal elements (TM₄) and a number (TM₄) of group 4 transition metals is less than 1.8;
c) the metal element (M) is a group 5 transition metal element, and a ratio (O_{b5}/TM₅) of a number (O_{b5}) of oxygen atoms bonded to the group 5 transition metal elements and a number (TM₅) of group 5 transition metals is less than 2.25; and
d) the metal element (M) is a group 6 transition metal element, and a ratio (O_{b6}/TM₆) of a number (O_{b6}) of oxygen atoms bonded to the group 6 transition metal elements and a number (TM₆) of group 6 transition metals is less than 2.7.
